(19) United States
(12) Patent Application Publication
(10) Pub. No.: US 2018/0249579 A1
(43) Pub. Date: Aug. 30, 2018

(54) Methods of Continuous Fabrication of Features in Flexible Substrate Webs and Products Relating to the Same

(71) Applicant: Corning Incorporated, Corning, NY (US)

(72) Inventors: Sean Matthew Garner, Elmira, NY (US); Samuel Odei Owusu, Horseheads, NY (US); Garrett Andrew Piech, Corning, NY (US); Scott Christopher Pollard, Big Flats, NY (US)

(21) Appl. No.: 15/754,144

(22) PCT Filed: Aug. 19, 2016
(86) PCT No.: PCT/US2016/047746

§ 371 Date: Feb. 21, 2018

Related U.S. Application Data
(60) Provisional application No. 62/208,282, filed on Aug. 21, 2015.
(60) Provisional application No. 62/232,076, filed on Sep. 24, 2015.

(51) Int. Cl. H05K 3/00; H05K 1/03; H05K 1/02; H05K 3/40; H05K 1/11; C03C 23/00; C03C 15/00; C03C 17/00

(52) U.S. Cl. CPC H05K 3/0029; H05K 1/0306; H05K 1/028; H05K 3/4038; H01L 21/4807; H05K 1/115; C03C 23/0025; C03C 15/00; C03C 17/002; H05K 3/002

(57) ABSTRACT

Methods of continuous fabrication of features in flexible substrates are disclosed. In one embodiment, a method of fabricating features in a substrate web includes providing the substrate web arranged in a first spool on a first spool assembly, advancing the substrate web from the first spool and through a laser processing assembly comprising a laser, and creating a plurality of defects within the substrate web using the laser. The method further includes advancing the substrate web through an etching assembly and etching the substrate web at the etching assembly to remove glass material at the plurality of defects, thereby forming a plurality of features in the substrate web. The method further includes rolling the substrate web into a final spool.

This application claims the benefit of priority to U.S. Application Nos. 62/208,282, filed on Aug. 21, 2015, and 62/232,076, filed on Sep. 24, 2015, the content of each of which is incorporated herein by reference in its entirety.

### BACKGROUND

There is increasing interest in creating features such as through-holes, blind-vias and other surface features in flexible substrates for a variety of applications. These applications include, but are not limited to, glass interposers, printed circuit boards, fluidics, displays, optical backplanes, and other opto-electronic or life-science applications in general. These flexible substrates, such as flexible glass substrates, are desired due to at least their dimensional stability. Current methods of creating features in flexible substrates involve bonding the sheet-form substrate to a frame for processing and handling. This is performed with both polymeric substrates as well as flexible glass. This method is used for polymer film to overcome flatness and dimensional stability issues during processing. This method may be used for flexible glass to enable handling of the substrate. Although this approach is useable, it is difficult to scale to large area substrates required for large area devices or high-throughput continuous manufacturing. Accordingly, this approach increases the cost of the end-products due to reduced through-put and an increased number of processing steps.

There exists a need for processing flexible substrate materials in a continuous manner to enable large-area devices and/or high-throughput manufacturing.

### SUMMARY

The embodiments disclosed herein relate to methods for producing features in flexible substrates in a continuous, roll-to-roll process prior to separating the substrate into individual components, such as wafers. The continuous, roll-to-roll processes described herein do not require a step of bonding the substrate to a rigid frame, and allow the features to be formed prior to individually separating the substrate into individual components (e.g., wafers) prior to fabricating the features. The continuous, roll-to-roll processes described herein may be utilized to fabricate feature and substrate geometries similar to provided by batch processing but with improved substrate handling.

There exists a need for processing flexible substrate materials in a continuous manner to enable large-area devices and/or high-throughput manufacturing. Free-standing web materials can be handled and conveyed very efficiently using roller-based systems, but use of roll-to-roll processing has not been demonstrated for dimensionally accurate via formation. Although roll-to-roll processing of polymer film is known and creating through-holes by punching or laser ablation methods are possible, polymer suffers from lack of dimensional stability. Polymer films stretch and distort during subsequent processing steps that cause the through-holes to become misaligned. This is the reason that polymer films are typically adhered to a processing frame. The specific need that exists is the ability to create through-holes in a dimensionally stable substrate using continuous processing.

In one embodiment, a method of fabricating features in a substrate web includes providing the substrate web arranged in a first spool, advancing the substrate web from the first spool and through a laser processing assembly comprising a laser, and creating a plurality of defects within the substrate web using the laser. The method further includes advancing the substrate web through an etching assembly and etching the substrate web at the etching assembly to remove glass material at the plurality of defects, thereby forming a plurality of features in the substrate web. The method further includes rolling the substrate web into a final spool.

In another embodiment, a method of fabricating features in a substrate web includes providing a substrate web arranged in a first spool on a first spool assembly, advancing the substrate web from the first spool toward a laser processing assembly comprising a laser, and creating a plurality of defects within the substrate web using the laser at the laser processing assembly. The method further includes advancing the substrate web toward a final spool assembly, and rolling the substrate web and an interleaf layer adjacent to the substrate web into a final spool using the final spool assembly.

In yet another embodiment, a glass substrate web comprises a plurality of through holes disposed within the glass substrate web, wherein the glass substrate web is rolled into a spool.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the representative embodiments.

FIG. 1A is a schematic illustration of a method and system for fabricating features in one or more substrate webs according to one or more embodiments described and illustrated herein;

FIG. 1B is a schematic illustration of another method and system for fabricating features in one or more substrate webs according to one or more embodiments described and illustrated herein;

FIG. 1C is a schematic illustration of another method and system for fabricating features in one or more substrate webs according to one or more embodiments described and illustrated herein;

FIG. 2 is a schematic illustration of a partial view of a substrate web after fabrication of features according to one or more embodiments described herein;

FIG. 3 is a schematic illustration of a partial view of a substrate web wherein segments of the substrate web have features formed therein according to one or more embodiments described and illustrated herein;

FIG. 4A is a schematic illustration of example laser processing components of a laser processing assembly to form defects within the substrate webs according to one or more embodiments described and illustrated herein;

FIG. 4B is a schematic illustration of a side view of a substrate web depicting the formation of a defect line due to the induced absorption along a focal line created by the laser processing components depicted in FIG. 4A according to one or more embodiments described and illustrated herein;

FIG. 5 is a schematic illustration of example laser processing components of a laser processing assembly to form defects within the substrate webs according to one or more embodiments described and illustrated herein;

FIG. 6A is a schematic illustration of an example etching assembly according to one or more embodiments described and illustrated herein;

FIG. 6B is a schematic illustration of an example etching assembly according to one or more embodiments described and illustrated herein;

FIG. 6C is a schematic illustration of an example etching assembly according to one or more embodiments described and illustrated herein;

FIG. 7 is a schematic illustration of a partial view of a spool comprising a substrate web and an interleaf layer according to one or more embodiments described and illustrated herein; and

FIG. 8 is a schematic illustration of a spool comprising a substrate web and an interleaf layer being positioned within an etching assembly according to one or more embodiments described and illustrated herein.

### DETAILED DESCRIPTION

The embodiments disclosed herein relate to methods for producing features in flexible substrates in a continuous, roll-to-roll process prior to separating the substrate into individual components, such as wafers. The continuous, roll-to-roll processes described herein do not require a step of bonding the substrate to a rigid support frame, and allow the features to be formed prior to individually separating the substrate into individual components (e.g., wafers) prior to fabricating the features. The continuous, roll-to-roll processes described herein may be utilized to fabricate feature and substrate geometries similar to those provided by batch processing but with improved substrate handling.

As described in more detail below, a substrate web is provided in a spool or flexible web. The substrate web is unrolled from the spool or flexible web and advanced toward a laser processing assembly, where a laser beam is used to form features, damage regions, or lines within the substrate web. In one embodiment, the substrate web is then advanced toward an etching assembly, where the substrate web is subjected to an etching process to remove substrate material around the damage regions created by the laser beam to open up the damaged regions and create features. As used herein, the term “feature” means a void within the substrate web having any shape or depth, and includes through-holes extending fully through a depth of the substrate web, blind-vias extending partially through a depth of the substrate web, slots extending through the depth of the substrate web, channels extending partially through the substrate web, and the like. The substrate web with the features formed therein is then rolled into a final spool, which may be easily handled for further processing, such as shipped to another facility for dicing, coating, device fabrication, lamination, or other processes. Various methods for fabricating features in flexible substrate webs are described in detail below.

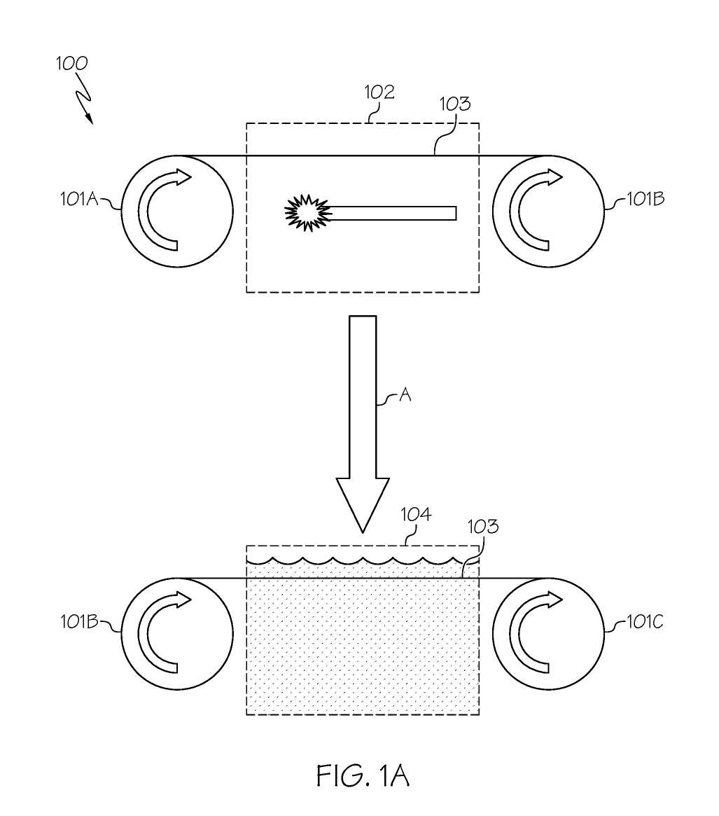

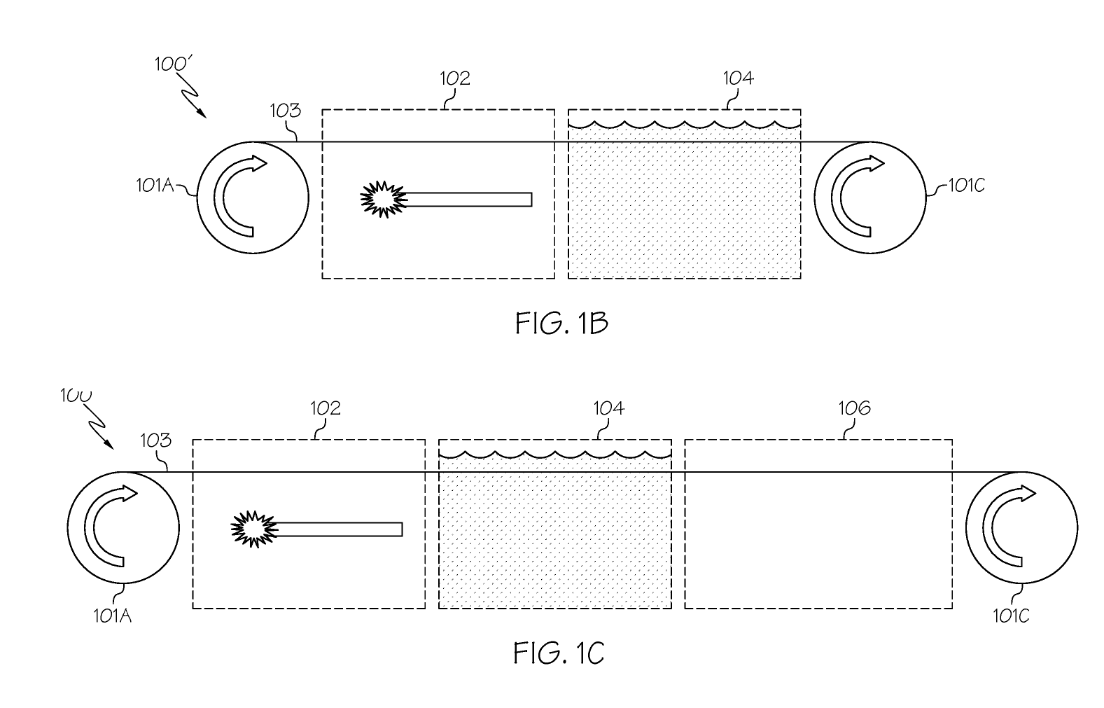

Referring now to FIG. 1A, a method and system 100 for fabricating features in a flexible substrate web 103 is schematically illustrated. Generally, the substrate web 103 is provided in a first spool 101A prior to processing. As used herein, the term “substrate web” means a glass substrate web, a glass-ceramic substrate web, or a ceramic substrate web. The term “substrate web” also includes a flexible substrate web comprising one or more of polymer, metal, glass, glass-ceramic, or ceramic materials. For example, the substrate web can comprise a flexible glass web that is capable of being wound into a roll. Also for example, different materials may be spliced, laminated, or joined together to create a roll. The different materials can each cover the entire width of the web or be individual discrete regions. As an example and not a limitation, the substrate web can be a polymer web carrier with individual discrete flexible glass regions laminated or bonded to it. These may be adhered covering the polymer web carrier or in locations of open frames. The glass substrate web may be fabricated from any glass material capable of being laser drilled and optionally etched as described herein. Similarly, the glass-ceramic substrate web and the ceramic substrate web may be fabricated from any glass-ceramic or ceramic material capable of being laser drilled and optionally etched as described herein. As non-limiting examples, EagleXG®, Lotus®, and Gorilla® Glass substrates fabricated by Corning, Incorporated of Corning, N.Y. may be processed using the methods described herein. As another non-limiting example, flexible yttria-stabilized zirconia may be processed using the methods described herein.

As stated above, the substrate web 103 is capable of being drilled by a laser exposure process. Accordingly, the substrate web 103 should be capable of receiving thermal energy with minimal dimensional change so that substrate web 103 does not need to be secured to a support frame during laser processing. For example, polyimide film typically used for high temperature electronics applications may experience unpredictable distortion in the range of 10 μm to 100 μm when subjected to thermal cycles. By comparison, the substrates described herein, such as glass substrates, do not have detectable distortion when subjected to the same thermal cycles. In addition to dimensional stability, the substrate web 103, or portions of the substrate web if it is a composite, should be capable of withstanding temperatures greater than about 500° C., have a Young's modulus greater than about 50 GPa, and/or have a hardness of greater than about 3 GPa.

The substrate web 103 should have a thickness such that it is capable of being rolled into a spool, as shown in FIG. 1A. In the case of a glass substrate, as a non-limiting example, the substrate web 103 may have a thickness of less than 300 μm. It should be understood that the substrate web 103 may take on other thicknesses depending on the composition and properties of the material.

The first spool 101A is disposed on a first spool assembly (not numbered) that mechanically rotates to unroll the substrate web 103, as depicted in FIG. 1A. The first spool assembly, as well as the other spool assemblies described herein, may be configured as any device capable of rotating and having the substrate web 103 rolled thereon.

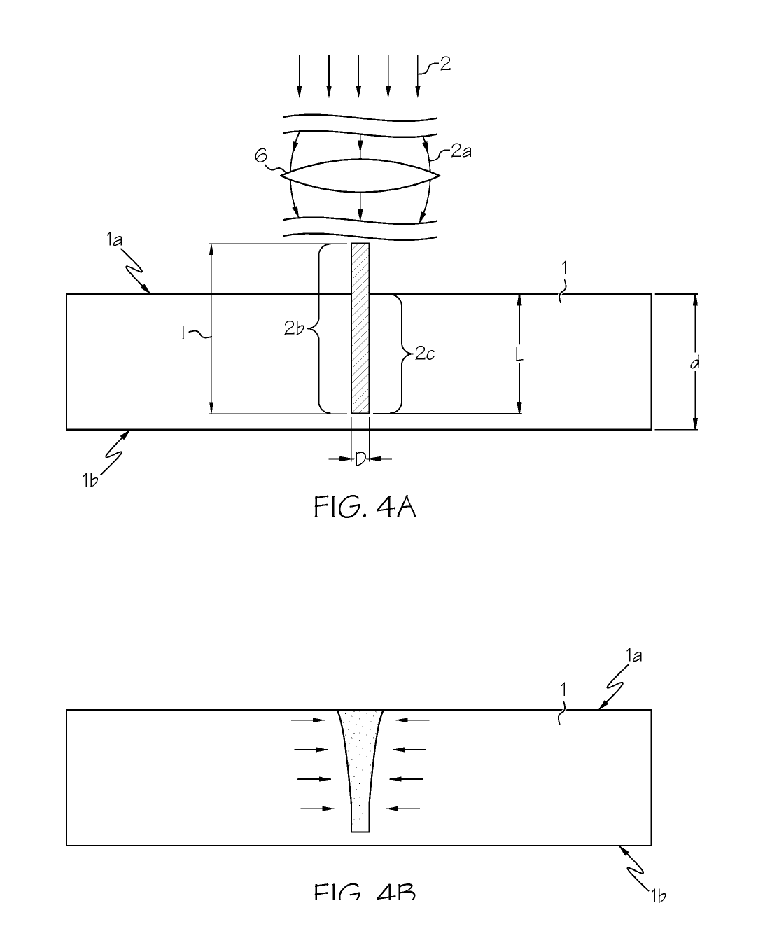

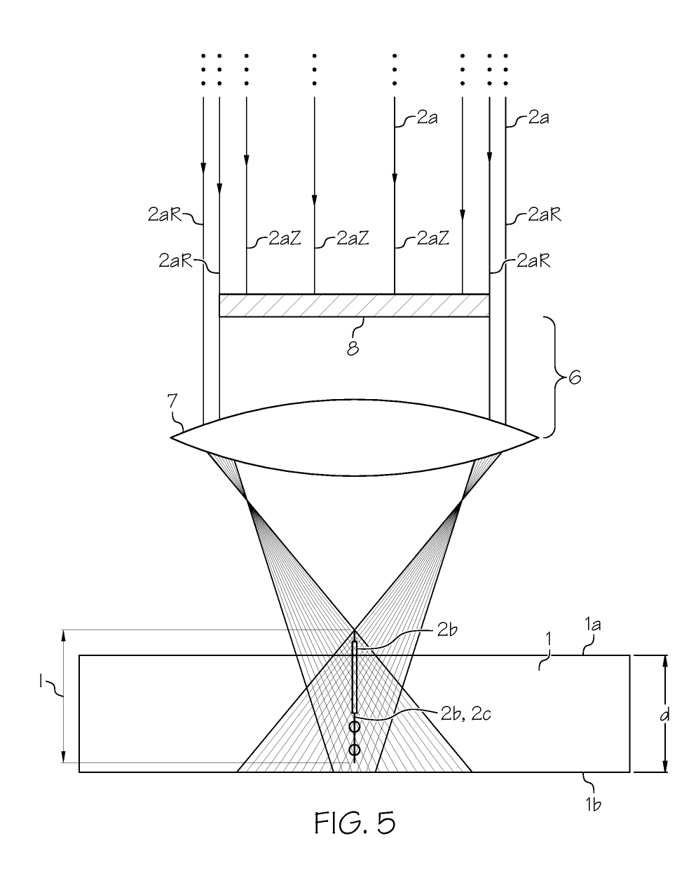

In the illustrated embodiment, the substrate web 103 passes through a laser processing assembly 102 as it is unrolled from the first spool 101A. As described in more detail below, the laser processing assembly 102 comprises one or more lasers operable to laser-drill a plurality of defects (not shown in FIG. 1A) on or through the substrate web 103. The defects may be through-holes, blind holes, defect lines, or damaged areas within the glass substrate formed by multi-photon absorption, as described in more detail below. Any laser process capable of forming laser-induced defects within the substrate web 103 may be utilized, depending on the end application and feature requirements. As an example, and not a limitation, the one or more lasers may be operable to produce a laser beam in the ultra-violet or infrared wavelength range. An example, non-limiting laser processing assembly is illustrated in FIGS. 4A, 4B and 5, and described in detail below.

It is noted that it is possible to process several substrate webs simultaneously. For example, a first spool 101A may include several rolled substrate webs so that the multiple substrate webs may be laser drilled simultaneously when arranged in a stacked relationship within the laser processing assembly 102.

In the example illustrated by FIG. 1A, the substrate web 103 is advanced from the laser processing assembly 102 toward a first intermediate spool assembly (not numbered) where the substrate web 103 is rolled into an intermediate spool 101B. After the substrate web 103 is fully rolled as the intermediate spool 101B, it is removed from the first intermediate spool assembly.

In alternative embodiments, the substrate web 103 is separated into a plurality of smaller segments that are then rolled into a plurality of smaller intermediate spools. These smaller segments may be formed by separating the substrate web across the width, across the length, in a combination of width and length, by delaminating, or by other methods. These smaller intermediate spools may then be unrolled and passed through the etching assembly 104. The substrate web 103 may be separated into the smaller segments by any known or yet-to-be-developed substrate separation technique.

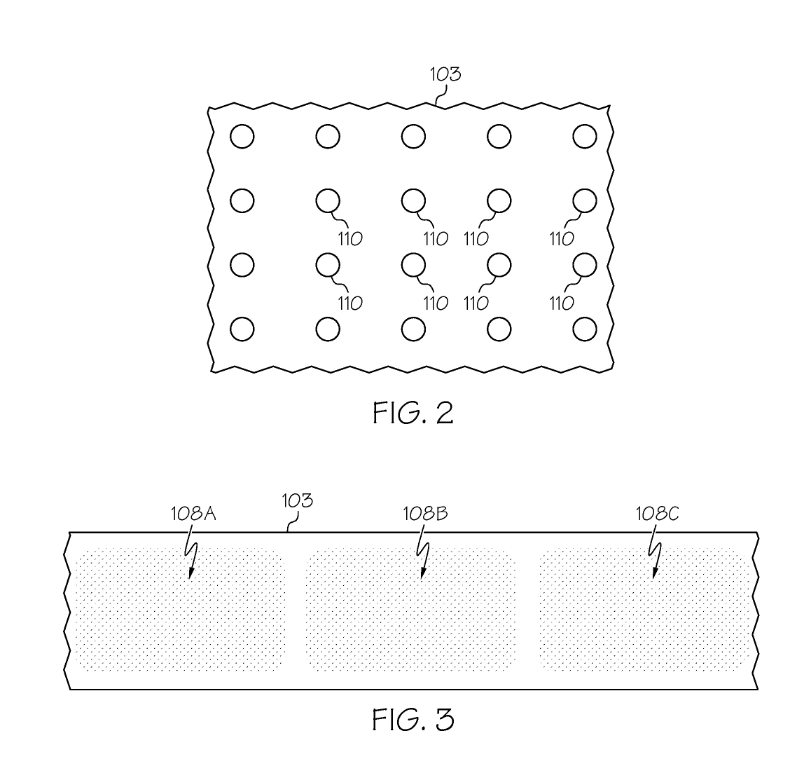

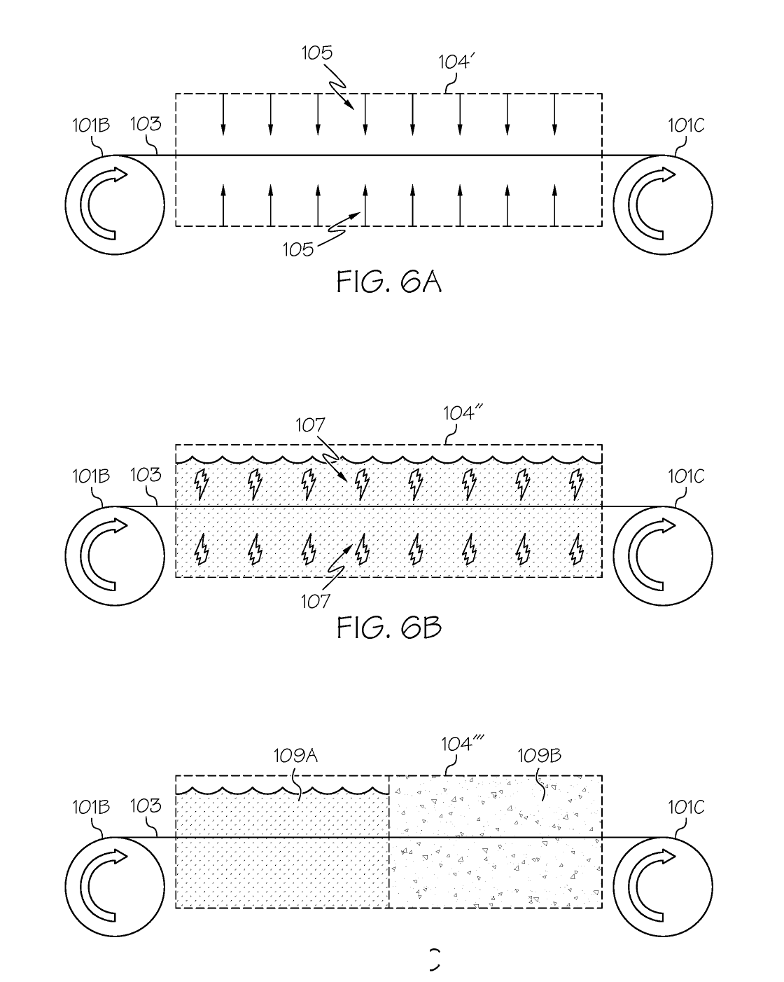

As indicated by arrow A, the example process continues by positioning the intermediate spool 101B (or multiple intermediate spools) on a second intermediate spool assembly (not numbered) that is operable to mechanically rotate as shown in FIG. 1A to unroll the substrate web 103 from the intermediate spool 101B. The substrate web 103 is advanced from the intermediate spool 101B such that it enters an etching assembly 104, where it is subjected to an etching process to open the defects created by the laser process to form the desired features. It is noted that the laser and etching processes depicted in FIG. 1A do not need to be consecutive. For example, the laser processing can occur first, followed by several device fabrication or other process steps, and then the etching process. Any known or yet-to-be developed etching process may be utilized to open or otherwise shape the features 110 into the desired shape. Example, not-limiting etching processes are schematically depicted in FIGS. 6A-6C and described in detail below. FIG. 2 depicts a plurality of features 110 configured as through holes in a portion of a substrate web 103 following the etching process. The shape of the holes can vary from cylindrical, conical, or other shape depending on the application requirements. Alternatively, the laser processing unit 102 may create sufficient features in the substrate material 103 without requiring an etching process so that the etching assembly 104 is not required.

After passing through the etching assembly 104, the substrate web 103 is advanced from the laser processing assembly 102 toward a final spool assembly (not numbered) where the substrate web 103 is rolled into a final spool 101C. After the substrate web 103 is fully rolled as the final spool 101C, it is removed from the final spool assembly. The final spool 101C comprises a rolled substrate web 103 having features 110 formed therethrough. As stated above, the features 110 may be through-holes, blind-vias, slots, channels, or other features. The final spool 101C may be then subjected to further processing, or shipped to a subsequent facility for further processing. Shipping the final spool 101C to a substrate processor may be easier and/or more cost effective than shipping thousands of individually singulated substrates, for example.

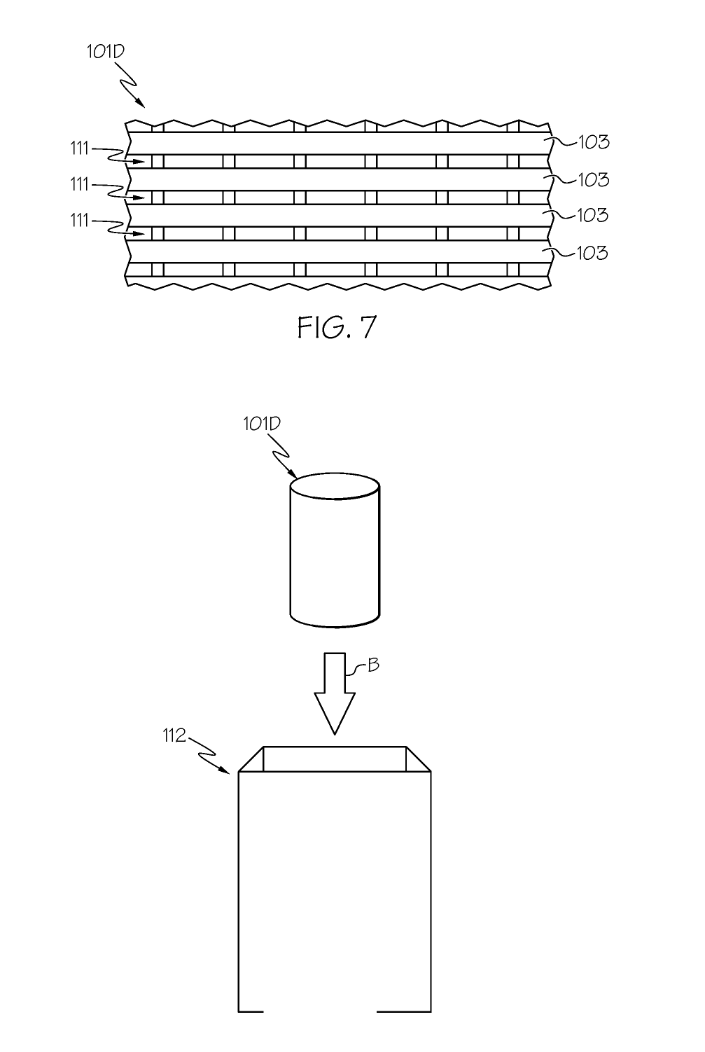

As noted above, it is possible to process several substrate webs simultaneously. During the etching process, there should be a gap present between surfaces of adjacent substrate webs to ensure that etchant reaches substantially all surfaces of the substrate webs. Therefore, one or more etchant-resistant interleaf layers may be disposed between adjacent substrate webs to provide a gap between the surfaces of adjacent substrate webs. An example interleaf layer 111 is depicted in FIG. 7 and described below. The one or more interleaf layers may be configured as a grid or otherwise have openings to allow etchant solution to reach substantially all surfaces of the one or more substrate webs.

The one or more interleaf layers may be provided at any time in the process prior to etching assembly 104. For example, the first spool 101A may comprise alternating substrate webs and interleaf layers such that the substrate webs and interleaf layers pass through the laser processing assembly 102. Alternatively, the one or more interleaf layers may be rolled with the substrate webs into one or more spools (e.g., a third intermediate spool) after the substrate webs pass through the laser processing assembly 102 and prior to passing the substrate webs through the etching assembly.

Referring now to FIG. 1B, another method and system 100′ for fabricating features in a flexible substrate web 103 is schematically illustrated. As described above with respect to FIG. 1A, the substrate web 103 is initially provided in a first spool 101A on a first spool assembly (not numbered). As the substrate web 103 is unrolled from the first spool 101A, it advances toward the laser processing assembly 102, where the defects are formed in the substrate web 103 by one or more lasers, as described above and in more detail below.

Rather than being rolled into an intermediate spool as depicted in FIG. 1A, the substrate web 103 advances directly toward the etching assembly 104. In this manner, the substrate web 103 passes directly from the laser processing assembly 102 to the etching assembly 104 after laser processing. As stated above, the etching assembly 104 may be configured as any assembly providing any etching process(es) capable of opening the plurality of defects into features. This can include wet processes and plasma processes. After exiting the etching assembly 104, the substrate web 103 is wound into a final spool 101C on a final spool assembly (not numbered). The final spool 101C may then be removed from the final spool assembly as described above.

The speed at which the substrate web 103 unrolls from the first spool 101A and is rolled into the final spool 101C, the speed of the laser processing within the laser processing assembly 102, and the duration of time that the substrate web 103 is within the etching assembly 104 should be coordinated such that the defects are properly formed and the features are properly opened during the etching process. In one embodiment, the substrate web 103 unrolls from the first spool 101A and the laser processing assembly fabricates defects continuously. The length of the etching assembly 104 is such that the substrate web 103 is exposed to the etching process for a duration that allows the defects to open to the desired feature shape.

In other embodiments, the substrate web 103 is unrolled from the first spool 101A discretely, such that the substrate web 103 stops within the laser processing assembly 102, wherein one or more lasers create a plurality of defects while the substrate web 103 is stopped for a period of time. FIG. 3 schematically depicts a portion of a substrate web 103 wherein individual segments 108A-108C are fabricated with features, while areas of the substrate web 103 not within the segments 108A-108C do not contain features. The substrate web 103 may be cut between the segments 108A-108C for further processing, if desired.

Referring now to FIG. 1C, another method and system 100″ for fabricating features in a substrate web is schematically depicted. Similar to the embodiment depicted in FIG. 1B, the substrate web 103 enters the etching assembly 104 directly after exiting the laser processing assembly 102. However, prior to being rolled into the final spool 101C, the substrate web 103 passes through one or more additional processing assemblies 106. The one or more processing assemblies may include, but is not limited to, cleaning (e.g., aqueous or plasma), via plating, application of one or more coatings to the substrate web 103, application of a dielectric material, planarization, metallization, printing, lamination, or additional via etching processes. For example, a polymeric coating can be applied to the substrate web after forming the plurality of defects. In some embodiments, the thickness of the coating (e.g., the polymeric coating) is less than a major dimension of the defects. For example, the thickness of the coating is at most about 90%, at most about 80%, at most about 70%, at most about 60%, at most about 50%, at most about 40%, at most about 30%, at most about 20%, at most about 10%, or at most about 5% of the major dimension of the defects. The major dimension of the defects can be expressed as an average largest dimension of the defects in the plane of the substrate web. For example, for defects with a circular cross-section in the plane of the substrate web, the major dimension can be expressed as the average diameter of the defects. In some embodiments, the coating comprises a dielectric material. Additionally, or alternatively, the coating comprises an adhesion layer configured to promote adhesion of a further coating onto the coated substrate web. For example, the further coating comprises a metallic material (e.g., by electroless metallization), a dielectric material, or another functional material. Following the one or more additional processing assemblies 106, the substrate web 103 is rolled into the final spool 101C, as described above. Alternatively, one or more additional processing steps 106 can occur between the laser processing assembly 102 and the etching assembly 104.

The laser processing assembly 102 may be configured as any laser processing system capable of quickly forming laser defects within the substrate web 103 as the substrate web 103 passes through the laser processing assembly 102. An example, non-limiting laser drilling process is described below and illustrated in FIGS. 4A, 4B and 5.

Generally, a laser beam is transformed to a laser beam focus line that is positioned within the bulk of the substrate web, such as a glass substrate, to create defects configured as damage lines within the substrate, as described in U.S. Pat. Appl. Pub. No. 2015/0166396, which is hereby incorporated by reference in its entirety. In accordance with processes described below, in a single pass, a laser can be used to create highly controlled full line damage through the substrate, with extremely little (<75 μm, often <50 μm) subsurface damage and debris generation. This is in contrast to the typical use of spot-focused laser to ablate material, where multiple passes are often necessary to completely perforate the glass thickness, large amounts of debris are formed from the ablation process, and more extensive sub-surface damage (>100 μm) and edge chipping occur.

Turning to FIGS. 4A and 4B, a method of laser processing a material includes focusing a pulsed laser beam 2 into a laser beam focal line 2b oriented along the beam propagation direction. The substrate 1 (i.e., substrate web 103) is substantially transparent to the laser wavelength when the absorption is less than about 10%, preferably less than about 1% per mm of material depth at this wavelength. As shown in FIG. 5, laser 3 (not shown) emits laser beam 2, which has a portion 2a incident to the optical assembly 6. The optical assembly 6 turns the incident laser beam into an extensive laser beam focal line 2b on the output side over a defined expansion range along the beam direction (length l of the focal line). The planar substrate 1 (i.e., the substrate web 103) is positioned in the beam path to at least partially overlap the laser beam focal line 2b of laser beam 2. The laser beam focal line is thus directed into the substrate. Reference 1a designates the surface of the planar substrate facing the optical assembly 6 or the laser, respectively, and reference 1b designates the reverse surface of substrate 1. The substrate or material thickness (in this embodiment measured perpendicularly to the planes 1a and 1b, i.e., to the substrate plane) is labeled with d.

As FIG. 4A depicts, substrate 1 is aligned perpendicular to the longitudinal beam axis and thus behind the same focal line 2b produced by the optical assembly 6 (the substrate is perpendicular to the plane of the drawing). The focal line being oriented or aligned along the beam direction, the substrate is positioned relative to the focal line 2b in such a way that the focal line 2b starts before the surface 1a of the substrate and stops before the surface 1b of the substrate, i.e. still focal line 2b terminates within the substrate and does not extend beyond surface 1b. In the overlapping area of the laser beam focal line 2b with substrate 1, i.e. in the substrate material covered by focal line 2b, the extensive laser beam focal line 2b generates (assuming suitable laser intensity along the laser beam focal line 2b, which intensity is ensured by the focusing of laser beam 2 on a section of length l, i.e. a line focus of length l) an extensive section 2c (aligned along the longitudinal beam direction) along which an induced absorption is generated in the substrate material. The induced absorption produces defect line formation in the substrate material along section 2c. The defect line is a microscopic (e.g., >100 nm and <0.5 micron in diameter) elongated “hole” (also called a perforation or a defect line) in the substrate using a single high energy burst pulse. Individual defect lines can be created at rates of several hundred kilohertz (several hundred thousand defect lines per second), for example. With relative motion between the source and the substrate, these holes can be placed adjacent to one another (spatial separation varying from sub-micron to many microns as desired). The defect line formation is not only local, but over the entire length of the extensive section 2c of the induced absorption. The length of section 2c (which corresponds to the length of the overlapping of laser beam focal line 2b with substrate 1) is labeled with reference L. The average diameter or extent of the section of the induced absorption 2c (or the sections in the material of substrate 1 undergoing the defect line formation) is labeled with reference D. This average extent D basically corresponds to the average diameter 6 of the laser beam focal line 2b, that is, an average spot diameter in a range of between about 0.1 micron and about 5 microns.

As FIG. 4A shows, the substrate material (which is transparent to the wavelength λ of laser beam 2) is heated due to the induced absorption along the focal line 2b arising from the nonlinear effects associated with the high intensity of the laser beam within focal line 2b. FIG. 4B illustrates that the heated substrate material will eventually expand so that a corresponding induced tension leads to micro-crack formation, with the tension being the highest at surface 1a.

The selection of a laser source is predicated on the ability to create multi-photon absorption (MPA) in transparent materials. MPA is the simultaneous absorption of two or more photons of identical or different frequencies in order to excite a molecule from one state (usually the ground state) to a higher energy electronic state (ionization). The energy difference between the involved lower and upper states of the molecule can be equal to the sum of the energies of the two photons. MPA, also called induced absorption, can be a third-order process, for example, that is several orders of magnitude weaker than linear absorption. MPA differs from linear absorption in that the strength of induced absorption can be proportional to the square or cube of the light intensity, for example, instead of being proportional to the light intensity itself. Thus, MPA is a nonlinear optical process.

Representative optical assemblies 6, which can be applied to generate the focal line 2b, as well as a representative optical setup, in which these optical assemblies can be applied, are described below. All assemblies or setups are based on the description above so that identical references are used for identical components or features or those which are equal in their function. Therefore only the differences are described below.

In order to achieve the required numerical aperture, the optics must, on the one hand, dispose of the required opening for a given focal length, according to the known Abbe formulae (N.A.=n sin (theta), n: refractive index of the glass or other material to be processed, theta: half the aperture angle; and theta=arctan (D/2f); D: aperture, f: focal length). On the other hand, the laser beam must illuminate the optics up to the required aperture, which is typically achieved by means of beam widening using widening telescopes between the laser and focusing optics.

The spot size should not vary too strongly for the purpose of a uniform interaction along the focal line. This can, for example, be ensured (see the embodiment below) by illuminating the focusing optics only in a small, circular area so that the beam opening and thus the percentage of the numerical aperture only vary slightly.

According to FIG. 4A (section perpendicular to the substrate plane at the level of the central beam in the laser beam bundle of laser radiation 2; here, too, laser beam 2 is perpendicularly incident to the substrate plane, i.e. incidence angle β is 0° so that the focal line 2b or the extensive section of the induced absorption 2c is parallel to the substrate normal), the laser radiation 2a emitted by laser 3 is first directed onto a circular aperture 8 which is completely opaque to the laser radiation used. Aperture 8 is oriented perpendicular to the longitudinal beam axis and is centered on the central beam of the depicted beam bundle 2a. The diameter of aperture 8 is selected in such a way that the beam bundles near the center of beam bundle 2a or the central beam (here labeled with 2aZ) hit the aperture and are completely absorbed by it. Only the beams in the outer perimeter range of beam bundle 2a (marginal rays, here labeled with 2aR) are not absorbed due to the reduced aperture size compared to the beam diameter, but pass aperture 8 laterally and hit the marginal areas of the focusing optic elements of the optical assembly 6, which, in this embodiment, is designed as a spherically cut, bi-convex lens 7.

As illustrated in FIG. 4A, the laser beam focal line 2b is not only a single focal point for the laser beam, but rather a series of focal points for different rays in the laser beam. The series of focal points form an elongated focal line of a defined length, shown in FIG. 4A as the length l of the laser beam focal line 2b. Lens 7 is centered on the central beam and is designed as a non-corrected, bi-convex focusing lens in the form of a common, spherically cut lens. The spherical aberration of such a lens may be advantageous. As an alternative, aspheres or multi-lens systems deviating from ideally corrected systems, which do not form an ideal focal point but a distinct, elongated focal line of a defined length, can also be used (i.e., lenses or systems which do not have a single focal point). The zones of the lens thus focus along a focal line 2b, subject to the distance from the lens center. The diameter of aperture 8 across the beam direction is approximately 90% of the diameter of the beam bundle (defined by the distance required for the intensity of the beam to decrease to 1/e of the peak intensity) and approximately 75% of the diameter of the lens of the optical assembly 6. The focal line 2b of a non-aberration-corrected spherical lens 7 generated by blocking out the beam bundles in the center is thus used. FIG. 4A shows the section in one plane through the central beam, and the complete three-dimensional bundle can be seen when the depicted beams are rotated around the focal line 2b.

It may be advantageous to position the focal line 2b in such a way that at least one of surfaces 1a, 1b is covered by the focal line, so that the section of induced absorption 2c starts at least on one surface of the substrate.

U.S. Pat. Appl. Pub. No. 2015/0166396 discloses additional embodiments for creating the laser focal line for drilling features into substrates that may be utilized. It should also be understood that other laser drilling methods that do not use a laser focal line may also be utilized.

Referring now to FIGS. 6A-6C, example etching processes that may be provided by the etching assembly 104 are schematically illustrated. As stated above, any etching process capable of opening the laser drilled features in the substrate web 103 may be used. Referring first to FIG. 6A, the example etching assembly 104′ is configured to etch the advancing substrate web 103 by spray etching. A plurality of nozzles (not shown) directs a plurality of spray jets 105 of etching solution at the substrate web 103. Although FIG. 6A illustrates spray jets 105 on both sides of the substrate web 103, embodiments may also only direct spray jets 105 on one side of the substrate web 103. The fluid velocity of the spray jets 105 may vary along the length and width of the etching assembly 104′. The spray etching conditions such as fluid velocity, oscillation, pulsing, etchant composition can vary from one surface of the substrate web 103 to the other.

The etching solution is not particularly limited and will depend on the material of the substrate web 103. An experiment was performed where EagleXG® Glass fabricated by Corning Incorporated of Corning N.Y., with a thickness of 70-80 μm, a width of 140 mm and a length of 10 m was laser drilled and then wound onto a core with a diameter of 150 mm. Roll and unroll spools were provided at each end of the etching assembly. The etching assembly provided oscillating spray of etching solution at 20 psi spray pressure. The etch chemistry was 3M HF and 1M H₂SO₄ at a temperature of 42° C. The glass sheet was advanced at a speed of 160 mm/minute for a residency time of the glass sheet in the etching assembly at 3.5 minutes. After etching, the glass sheet was re-wound onto a 150 mm diameter spool using a 50 μm thick polyethylene-napthalate (“PEN”) film as an interleaf material.

FIG. 6B schematically illustrates an etching assembly 104″ providing aqueous etching wherein the substrate web 103 is submerged in etching solution. As noted above, any etching solution chemistry may be used depending on the properties of the substrate web 103. Although not shown in FIG. 6B, etchant-resistant rollers may be provided in the etching assembly 104″ to push the substrate web 103 downward such that it is fully submerged in the etching solution. As shown in FIG. 6B, ultrasonic energy and/or agitation (represented by shapes 107) may be applied to the etching solution and/or the substrate web 103 to further encourage etching of the features. The applied energy or agitation may be directed differently across the width, length, or surface of the substrate web 103.

FIG. 6C schematically illustrates an etching assembly 104′″ providing multiple etching zones in the form of etching zones 109A and 109B. It should be understood that any number of etching zones may be provided depending on the application. In the illustrated embodiment, etching zone 109A is an aqueous etching zone (which may or may not provide ultrasonic energy or agitation) while subsequent etching zone 109B is a dry etching zone. It should be understood that other etching zones may be provided in lieu of, or in addition to, illustrated etching zones 109A and 109B. For example, the etching zones may provide spray processes or substrate submersion.

The different etching zones may be optimized specifically with different etch conditions. Fast changes in etch conditions is difficult to achieve in batch processing where individual sheets of substrates are etched. However, in a continuous or roll-to-roll process as described herein, sequential sets of spray nozzle can vary the etch composition, provide a water rinse, change temperature, add or remove agitation, and the like as the substrate web 103 advances through the etching assembly 104.

As noted above, each surface of the substrate web 103 may be processed independently. For example, both surfaces of the substrate web 103 can be etched the same or differently. Or, in other configurations, only one surface of the substrate web 103 may be etched. With the ability to etch each surface differently, there is the possibility of creating at the same time features by aggressively etching a first surface and lightly etching the other surface. This could also be used to create through holes by etching aggressively from one surface but only surface features on the other surface due to a light etch. The processing of each surface of the substrate may also be staggered. The etch conditions may also be varied across the horizontal width of the substrate.

Not only does continuous etching affect the feature properties, but it can also affect the substrate web edges and overall mechanical reliability. Etching of the edges of the substrate web can eliminate or reduce flaws in the substrate web to thereby increase bend strength. Etching near the edges can also produce a rounded, tapered, or varying thickness edge profile. The etching process produces a thinning of the substrate web as well. This thinning can be uniform over the substrate web width or it could more aggressively create thinner regions in the substrate web for mechanical, cutting, or device functionality purposes. These variations are possible by varying the etch conditions across the substrate surface or by masking techniques.

In some embodiments, the substrate web 103 is passed or advanced through one or more of the laser processing assembly, the etching assembly, or additional processing assemblies in a continuous process (e.g., as shown in FIGS. 1A, 1B, 1C, 6A, 6B, and 6C). For example, each end of the substrate web 103 remains attached to a spool as the substrate web is passed sequentially through one or more of the laser processing assembly, the etching assembly, or additional processing assemblies in a roll-to-roll process. Also for example, one end of the substrate web 103 remains attached to a spool as the substrate web is passed sequentially through one or more of the laser processing assembly, the etching assembly, or additional processing assemblies and then singulated to form individual segments in a roll-to-sheet process.

In alternative embodiments, the substrate web 103 may be separated into individual segments after the laser process. Rather than roll-to-roll processing, the individual segments of the substrate web 103 may be continuously passed through the etching assemblies described herein. In some embodiments, the substrate web 103 may enter the etching assembly 104 as an unrolled sheet, and then be rolled into a spool after passing through the etching assembly.

Referring now to FIGS. 7 and 8, in some embodiments an entire spool 101D is etched in spool form following the laser process rather than by continuously passing the substrate web 103 through the etching assembly 104. FIG. 7 schematically illustrates a portion of a final spool 101D of a rolled substrate web 103. To ensure that etching solution reaches substantially all surface areas of the substrate web 103, a gap should be present between adjacent surfaces of the substrate web 103. As shown in FIG. 7, an etchant-resistant interleaf layer 111 is disposed between adjacent surfaces of the substrate web 103. The interleaf layer 111, which may be configured as a grid or otherwise comprise openings, provides for gaps between adjacent surfaces of the substrate web 103. This allows the etchant solution to flow in between the surfaces of the substrate web 103 when the final spool 101D is submerged in the etching solution. The interleaf layer 111 may be applied before or after the laser processing assembly 102. The final spool 101D may also include a plurality of substrate webs and a plurality of interleaf layers.

After the passing through the laser processing assembly 102 and being rolled into the final spool 101D (or intermediate spool 101B as shown in FIG. 1A), the substrate web 103 is placed into an etching assembly 112 as indicated by arrow B. The etching solution chemistry and etching duration will depend on the material of the substrate web 103 and the desired properties (e.g., hole diameter, substrate web thickness, and the like). The resulting product is a spool of a rolled substrate web having features formed therein. After etching, the final spool 101D may be cleaned (e.g., aqueous cleaning or plasma cleaning) and/or subjected to further processing. For example, the final spool 101D may be easily packaged and shipped to another facility for further processing.

It should now be understood that embodiments described herein provide for continuous roll-to-roll fabrication of features within flexible substrate webs, such as glass sheets, glass-ceramic sheets, or ceramic sheets. One or more substrate webs are unrolled from a spool and pass through a laser processing assembly where defects within the one or more substrate webs are created by a laser. The one or more substrate webs are then continuously passed through an etching assembly to chemically etch the one or more glass substrate webs to open the defects into features having desired dimensions. The roll-to-roll continuous processing reduces the number of process steps over traditional fabrication methods, and allows for easy handling of the substrate webs in spool form.

While exemplary embodiments have been described herein, it will be understood by those skilled in the art that various changes in form and details may be made therein without departing from the scope encompassed by the appended claims.

1. A method of fabricating features in a substrate web, the method comprising:
advancing the substrate web from a first spool;
advancing the substrate web through a laser processing assembly comprising a laser;
creating a plurality of defects within the substrate web using the laser;
advancing the substrate web through an etching assembly;
etching the substrate web at the etching assembly to remove material at the plurality of defects, thereby forming a plurality of features in the substrate web; and
rolling the substrate web into a final spool.

2. The method of claim 1, wherein the substrate web comprises a glass substrate web, a glass-ceramic substrate web, or a ceramic substrate web.

3. (canceled)

4. The method of claim 1, further comprising, prior to advancing the substrate web through the etching assembly, rolling the substrate web into an intermediate spool, and advancing the substrate web from the intermediate spool toward the etching assembly.

5. The method of claim 1, further comprising, prior to advancing the substrate web through the etching assembly, rolling the substrate web into an intermediate spool, and after advancing the substrate web through the laser processing assembly, rolling the substrate web with one or more additional substrate webs having a plurality of defects formed therein and one or more interleaf layers disposed between adjacent substrate webs, thereby forming a third intermediate spool.

6. The method of claim 5, further comprising advancing the substrate web, the one or more interleaf layers, and the one or more additional substrate webs toward the etching assembly.

7. The method of claim 1, wherein the substrate web is advanced directly from the laser processing assembly to the etching assembly.

8. (canceled)

9. The method of claim 1, wherein the first spool comprises at least one additional substrate web.

10-11. (canceled)

12. The method of claim 1, further comprising applying one or more coatings to the substrate web.

13. The method of claim 12, wherein the one or more coatings comprises a dielectric material.

14. The method of claim 1, wherein the substrate web has a thickness of less than 300 μm.

15. The method of claim 1, wherein creating the plurality of defects within the substrate web using the laser comprises:
pulsing and focusing the laser beam into a laser beam focal line oriented along a beam propagation direction and directed into the substrate web, the laser beam focal line generating an induced absorption within the substrate web, the induced absorption producing a defect in the form of a defect line along the laser beam focal line within the substrate web; and
translating the substrate web and the laser beam relative to each other, thereby forming the plurality of defects.

16. The method of claim 1, wherein the etching assembly comprises a plurality of etching zones.

17. The method of claim 1, wherein the etching assembly is configured to etch the substrate web by one or more of the following etching processes: spray etching, aqueous etching, or dry etching.

18. A method of fabricating features in a glass substrate web, the method comprising:
continuously advancing the glass substrate web from a first spool through a laser processing assembly comprising a laser;
creating a plurality of defects within the glass substrate web using the laser at the laser processing assembly; and
rolling the glass substrate web into a final spool.

19. The method of claim 18, further comprising:
continuously advancing the glass substrate web toward a final spool assembly; and
rolling the glass substrate web and an interleaf layer adjacent to the glass substrate web into the final spool at the final spool assembly.

20. The method of claim 19, further comprising etching the final spool while the glass substrate web is rolled into the final spool.

21. The method of claim 19, wherein the interleaf layer is configured such that a first surface and a second surface of the glass substrate web are separated when the glass substrate web is rolled into the final spool.

22. A glass substrate web comprising a plurality of through holes disposed within the glass substrate web, wherein the glass substrate web is rolled into a spool.

23. The glass substrate web of claim 22, wherein the glass substrate web has a thickness of less than 300 μm.

24. The glass substrate web of claim 22, further comprising a coating applied thereto.

25. The glass substrate web of claim 24, wherein the coating comprises a dielectric material.
